(19) United States
(12) Patent Application Publication
(10) Pub. No.: US 2019/0239368 A1
(43) Pub. Date: Aug. 1, 2019

(54) ELECTRICAL BOX ADAPTER PLATE

(71) Applicant: Zykronix, Inc., Englewood, CO (US)

(72) Inventor: David Ghaemi, Castle Rock, CO (US)

(21) Appl. No.: 15/884,918

(22) Filed: Jan. 31, 2018

(51) Int. Cl. H05K 5/02; H05K 5/00; F16M 13/02

(52) U.S. Cl. CPC H05K 5/0217; H05K 5/0017; H02G 3/18; F16M 13/02; H05K 5/0247

(57) ABSTRACT

An adapter plate is described that allows a display device to be mounted to a variety of standardized electrical boxes. In one embodiment, the adapter plate includes a first surface that contacts the display device, a second surface that contacts the standardized electrical outlet box, a first pair of mounting holes through the adapter plate that are separated from each other by a distance defined by screw receptacles on a first type of the standardized electrical outlet box, and a second pair of mounting holes through the adapter plate that are separated from each other by a distance defined by screw receptacles on a second type of the standardized electrical outlet box. The adapter plate further includes a pair of tabs that extend from the first surface that mate to the display device and an access opening through the adapter plate that is sized to pass an electrical cable.

### FIELD

This disclosure relates to the field of home automation devices, and in particular, to mounting home automation display devices.

### BACKGROUND

Home automation involves the control and automation of heating, cooling, lighting, ventilation, and security in the home. Home automation may also involve the control of home appliances, such as refrigerators, washers and dryers, ovens, etc. Typically, Wi-Fi is used to provide the network infrastructure for the connected devices.

Home automation suffers from fragmentation and a lack of industry standards. Typically, different manufacturers implement proprietary mounting and networking implementations that make it difficult to integrate home automation devices into standard building practices. For example, home automation systems typically include various display systems distributed around the home that allow the homeowner the ability to monitor and control the various devices in the home. Yet, installing such display systems during or after construction of a home may involve the use of proprietary mounting systems that add complexity, cost, and risk of error to construction or renovation crews. Further, different regions around the world utilize different standardized electrical outlet boxes, thereby compounding the problems associated with installations in different world markets. Thus, it would be desirable to provide more efficient mounting systems for these types of in-home automation display systems.

### SUMMARY

Embodiments described herein provide an adapter plate that allows a display device to be mounted to a variety of standardized electrical boxes. The adapter plate allows a display device to be mounted to various electrical outlet boxes that are in use in different regions of the world, which allows the adapter plate to be interchangeably used in a variety of regions.

One embodiment comprises an adapter plate that mounts a display device to a standardized electrical outlet box. The adapter plate includes a first surface that contacts the display device, and a second surface opposite the first surface that contacts the standardized electrical outlet box. The adapter plate further includes a first pair of mounting holes through the adapter plate that are separated from each other by a distance defined by screw receptacles on a first type of the standardized electrical outlet box. The adapter plate further includes a second pair of mounting holes through the adapter plate that are separated from each other by a distance defined by screw receptacles on a second type of the standardized electrical outlet box. The adapter plate further includes a pair of tabs that extend from the first surface that mate to the display device, and an access opening through the adapter plate that is sized to pass an electrical cable from the standardized electrical outlet box to the display device.

Another embodiment comprises a rectangular adapter plate that includes a firs surface and a second surface that is opposite the first surface. The rectangular adapter plate further includes an access opening through the rectangular adapter plate that is sized to pass an electrical cable. The rectangular adapter plate further includes a first pair of mounting holes through the rectangular adapter plate that are separated from each other by a distance defined by screw receptacles of a first type of standardized electrical outlet box, where the first pair of mounting holes are disposed between the access opening and a perimeter of the rectangular adapter plate, and a second pair of mounting holes through the rectangular adapter plate that are separated from each other by a distance defined by screw receptacles of a second type of standardized electrical outlet box, where the second pair of mounting holes are disposed between the first pair of mounting holes and the access opening. The rectangular adapter plate further includes a pair of tabs that extend from the first surface.

Another embodiment comprises an adapter plate that mounts a display device to a standardized electrical outlet box. The adapter plate includes a first surface configured to contact the display device, a second surface configured to contact the standardized electrical outlet box, and an access opening through the adapter plate that is sized to pass an electrical cable from the standardized electrical outlet box to the display device. The adapter plate further includes a first mounting hole that is disposed between the first edge and the access opening, and a second mounting hole that is disposed between the second edge and the access opening, where the first mounting hole and the second mounting hole are separated from each other by a distance defined by screw receptacles on a first type of standardized electrical outlet box. The adapter plate further includes a third mounting hole that is disposed between the first mounting hole and the access opening, and a fourth mounting hole that is disposed between the second mounting hole and the access opening, where the third mounting hole and the fourth mounting hole are separated from each other by a distance defined by screw receptacles on a second type of standardized electrical outlet box. The adapter plate further includes a first tab and a second tab that extend from the first surface and attach to the display device.

The features, functions, and advantages that have been discussed can be achieved independently in various embodiments or may be combined in yet other embodiments, further details of which can be seen with reference to the following description and drawings.

### DESCRIPTION OF THE DRAWINGS

Some embodiments are now described, by way of example only, and with reference to the accompanying drawings. The same reference number represents the same element or the same type of element on all drawings.

FIG. 1 is a perspective view of an adapter plate in an illustrative embodiment.

FIG. 2 illustrates the adapter plate of FIG. 1 in another illustrative embodiment.

FIG. 3 is a view of restrictors along a z-axis for the adapter plate of FIG. 2 in an illustrative embodiment.

FIG. 4 is a view of the restrictors of FIG. 3 engaged with walls of a standardized electrical outlet box in an illustrative embodiment.

FIG. 5 illustrates the adapter plate of FIG. 1 in another illustrative embodiment.

FIG. 6 is a view of restrictors of FIG. 5 along the x-axis in an illustrative embodiment.

FIG. 7 is a view of the restrictors of FIG. 5 engaged with walls of a standardized electrical outlet box in an illustrative embodiment.

FIG. 8 is a perspective view of another adapter plate in an illustrative embodiment.

FIG. 9 is a 3-dimensional view of an assembly in an illustrative embodiment.

FIG. 10 is another 3-dimensional view of the adapter plate of FIG. 9 in an illustrative embodiment.

FIG. 11 illustrates features along a bottom surface of the adapter plate of FIG. 9 in an illustrative embodiment.

FIG. 12 is a 3-dimensional view of an assembly in an illustrative embodiment.

FIG. 13 is a 3-dimensional view of another assembly in an illustrative embodiment.

### DETAILED DESCRIPTION

The figures and the following description illustrate specific exemplary embodiments. It will be appreciated that those skilled in the art will be able to devise various arrangements that, although not explicitly described or shown herein, embody the principles described herein and are included within the contemplated scope of the claims that follow this description. Furthermore, any examples described herein are intended to aid in understanding the principles of the disclosure, and are to be construed as being without limitation. As a result, this disclosure is not limited to the specific embodiments or examples described below, but by the claims and their equivalents.

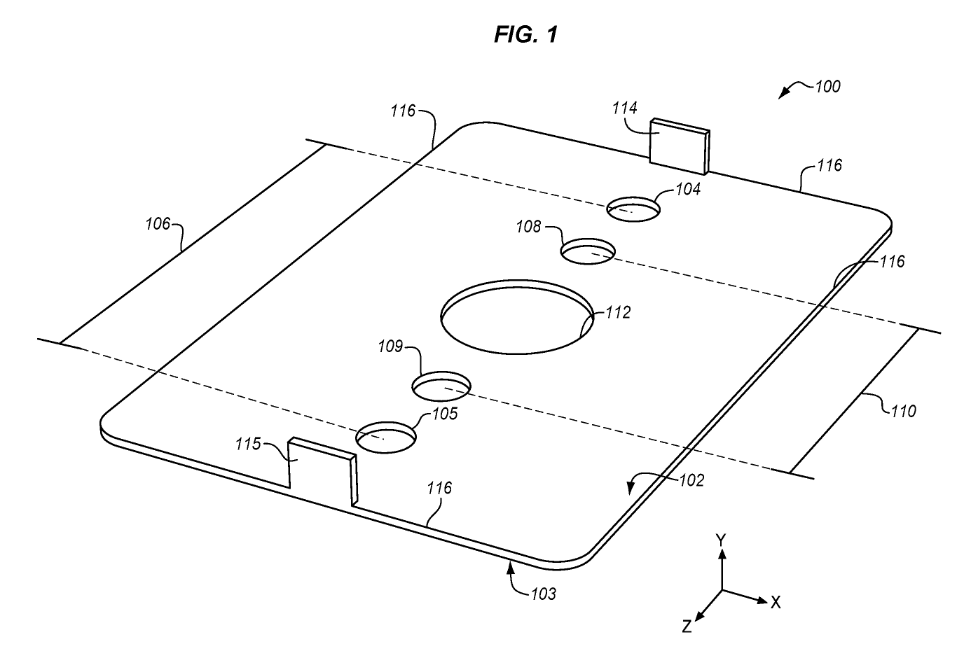

FIG. 1 is a perspective view of an adapter plate 100 in an illustrative embodiment. As described herein, adapter plate 100 is used to mount a display device (not shown in FIG. 1) to a standardized electrical outlet box (also not shown in FIG. 1.). The display device includes any component, system, or device that interacts with a user via a display and/or a display with a touch panel interface. For instance, the display device may comprise a display and control device for a home automation system. The display device may therefore be installed in a home and used to control various devices in the home, such as heating systems, cooling systems, ventilation systems, washers, dryers, ovens, security systems, etc. Typically, the display device interacts with the various systems in the home via a network, which may be wired or wireless. For instance, the display device may utilize Power Over Ethernet to both communicate with a network in the home, and be powered by the network.

The standardized electrical outlet box comprises any component, system, or device that is able to provide an electrical wiring termination point for an electrical outlet and/or an electrical switch. In one example, the standardized electrical outlet box may comprise an old-work box, which is used to install electrical wiring after drywall has been installed. In another example, the standardized electrical outlet box may comprise a new-work box, which is installed before drywall is installed. Old-work and new-work boxes may be referred to as gang boxes. Gang boxes may be single gang boxes, double gang boxes, or triple gang boxes. A single gang box is typically used to install one electrical outlet or switch, while double and triple gang boxes are used to install two or three electrical outlets or switches, respectively. Further, different regions in the world utilize different standardized electrical outlet boxes. For instance, the type of electrical outlet boxes used in the United States is different than the type of electrical outlet boxes used in Europe or the United Kingdom. In the embodiments described herein, adapter plate 100 is able to mount the display device to a variety of different standardized electrical outlet boxes. In this embodiment, adapter plate 100 includes a front surface 102 and an opposing back surface 103. Front surface 102 is configured to be mounted towards the display device, while back surface 103 is configured to be mounted towards the standardized electrical outlet box. Front surface 102 and back surface 103 may be referred to as a first surface and a second surface, respectively, in some embodiments.

Adapter plate 100 includes mounting holes 104-105 through adapter plate 100, which may be referred to as a first pair of mounting holes in some embodiments. In the embodiments described herein, the term “through” refers to an opening that traverses through an adapter plate 100 from one exterior surface (e.g., front surface 102) to another exterior surface (e.g., back surface 103).

In this embodiment, mounting holes 104-105 are separated from each other by a distance 106 defined by screw receptacles on a first type of standardized electrical outlet box. For instance, distance 106 between mounting holes 104-105 may be defined based on the separation between screw receptacles on a United States (US) 1-gang work box. The 1-gang work box may be a new-work box or an old-work box as desired. Further, as the separation between screw receptacles on a US 1-gang work box is identical to the separation between screw receptacles on a US 2-gang and a US 3-gang work box, adapter plate 100 may be mounted to any of the US 1-gang, US 2-gang, and US 3-gang work boxes that are commonly used in the construction industry in the United States.

Adapter plate 100 in this embodiment further includes mounting holes 108-109 through adapter plate 100, which may be referred to as a second pair of mounting holes in some embodiments. Mounting holes 108-109 are separated from each other by a distance 110 defined by screw receptacles on a second type of standardized electrical outlet box. For instance, distance 110 between mounting holes 108-109 may be defined based on the separation between screw receptacles on a European (EU) round wall box, which is a common electrical outlet box in Europe, and/or a United Kingdom (UK) square wall box, which is a common electrical outlet box in the UK.

In this embodiment, adapter plate 100 includes an access opening 112 through adapter plate 100 from front surface 102 to back surface 103. Access opening 112 in this embodiment is sized to pass an electrical cable (e.g., an Ethernet cable, a power cable, etc.) from the standardized electrical outlet box to the display device. For instance, during new construction, a home may be wired using POE, which provides power and Ethernet signaling between the display device and the home network. A POE cable may terminate within the standardized electrical outlet box, which is then connected to the display device via access opening 112. The POE cable in this example provides both electrical power and wired connectivity to the home network.

In another example, the display device may operate on a wireless network in the home (e.g., Wi-Fi), while being electrically powered by a power cable that traverses from the standardized electrical outlet box to the display device via access opening 112. The electrical cable in this example provides electrical power to the display device, while an internal wireless radio within the display device operates to provide wireless connectivity to the home network.

In this embodiment, adapter plate 100 further includes tabs 114-115 which extend from front surface 102 of adapter plate 100. In this embodiment, tabs 114-115 mate to the display device. For example, tabs 114-115 may slide or snap into recesses of the display device, thereby mounting the display device to adapter plate 100. In another example, screws within the display device may be used to secure the display device to tabs 114-115 in order to mount the display device to adapter plate 100.

Although FIG. 1 illustrates a particular orientation, size, and spatial relationship between the various features of adapter plate 100, any such orientation, size, and spatial relationship is merely illustrated such for purposes of discussion. For instance, adapter plate 100 may have a different size, shape, and/or thickness. Mounting holes 104-105 and mounting holes 108-109 may be round, square, slotted, or be formed to have other shape as desired. Access opening 112 may be round, square, slotted, or be formed to have other shapes as desired. Further, the position and size of tabs 114-115 may extend from front surface 102 at different locations of front surface 102, and/or tabs 114-115 may be of a different shape and/or thickness, etc.

In some embodiments, tabs 114-115 extend from front surface 102 at a perimeter 116 of adapter plate 100. Perimeter 116 of adapter plate 100 is defined as the outermost edges of adapter plate 100. In some embodiments, tabs 114-115 each form planar surfaces that are perpendicular to front surface 102. For instance, tabs 114-115 may be formed from a thin metal that extends vertically from front surface 102, thereby forming a perpendicular surface with respect to a substantially planar front surface 102.

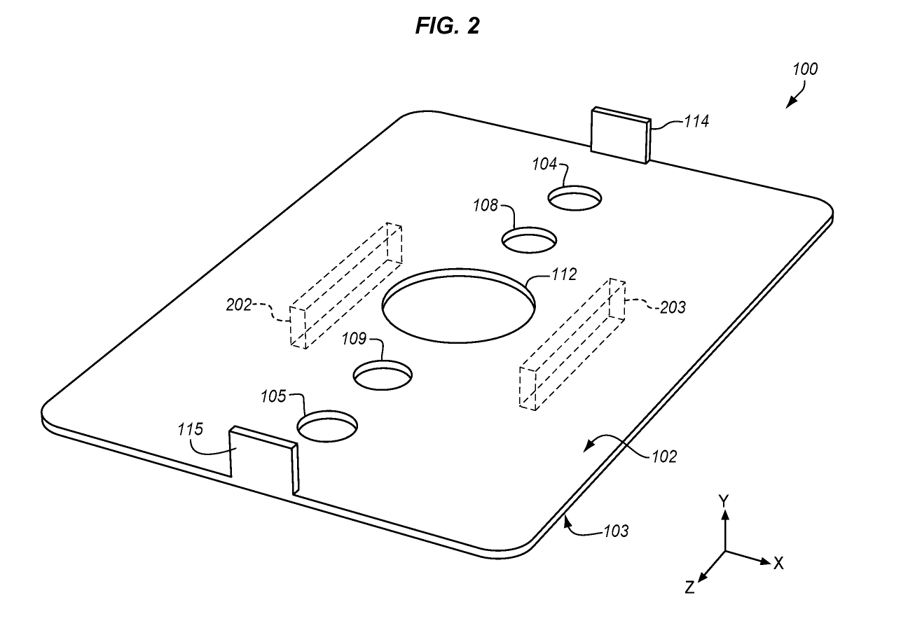

FIG. 2 illustrates adapter plate 100 in another illustrative embodiment. In this embodiment, adapter plate 100 includes restrictors 202-203 which extend from back surface 103 of adapter plate 100. Restrictors 202-203 in this embodiment are separated by a distance 204 that is defined by the interior dimensions of the first and/or the second type of standardized electrical outlet box. FIG. 2 in particular illustrates restrictors 202-203 located along back surface 103 in a position whereby restrictors 202-203 are able to engage with the interior walls of a standardized electrical outlet box.

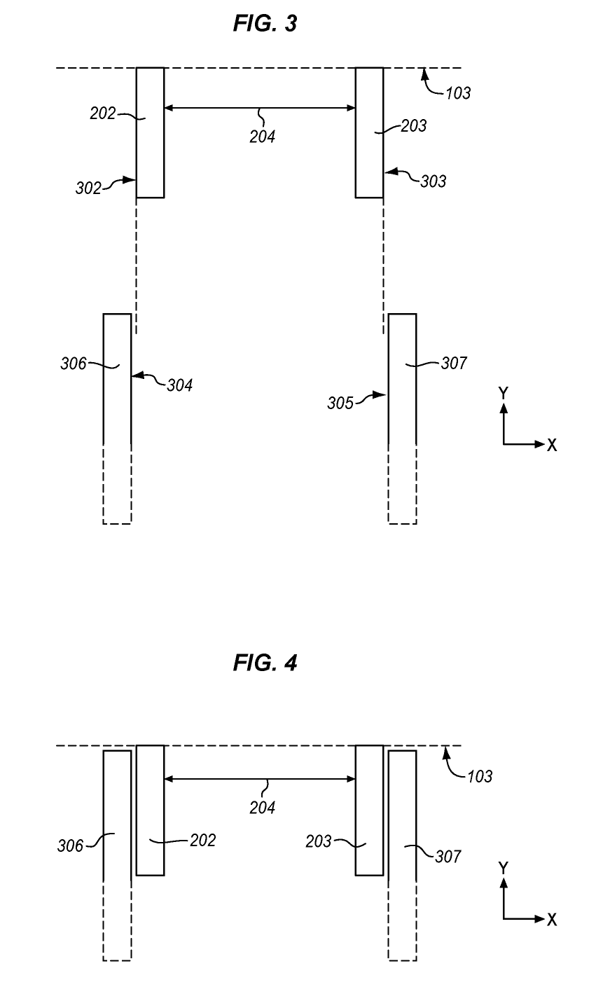

FIG. 3 is a view of restrictors 202-203 along the z-axis of FIG. 2 in an illustrative embodiment. In this view, outer surfaces 302-303 of restrictors 202-203 engage with inner surfaces 304-305 of walls 306-307 of a standardized electrical outlet box. This prevents movement of adapter plate 100 in the x-axis direction. In particular, outer surface 302 of restrictor 202 forms a planar surface (which is into the page in FIG. 3) and is able to engage with inner surface 304 of wall 306 of a standardized electrical outlet box. Outer surface 303 of restrictor 203 forms a planar surface (also into the page in FIG. 3) and is able to engage with inner surface 305 of wall 307 of the standardized electrical outlet box. FIG. 4 is a view of restrictors 202-203 and walls 306-307 when engaged together in an illustrative embodiment.

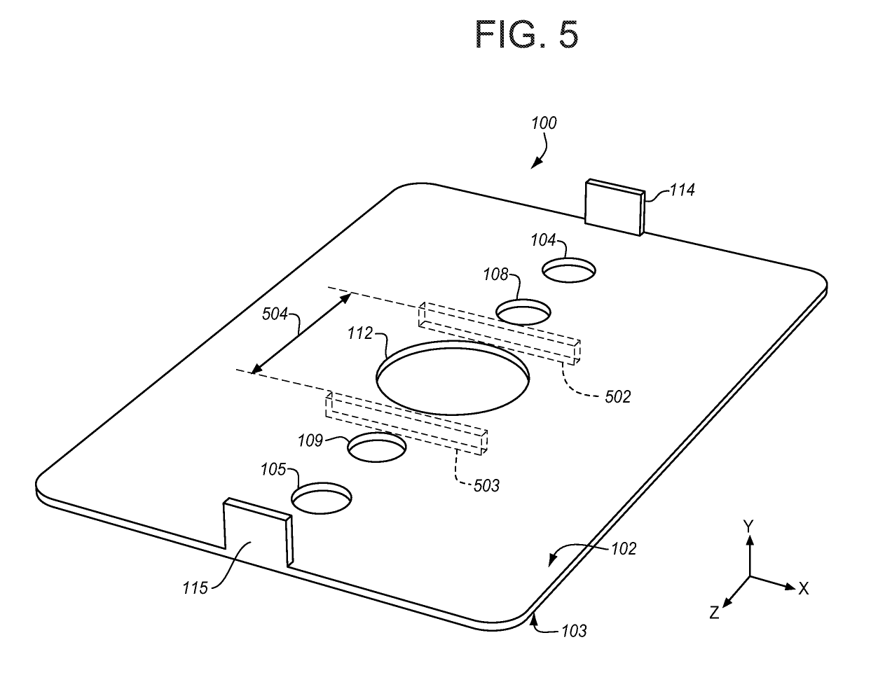

FIG. 5 illustrates adapter plate 100 in another illustrative embodiment. In this embodiment, adapter plate 100 further includes restrictors 502-503 which extend from back surface 103 of adapter plate 100. Restrictors 502-503 in this embodiment are separated by a distance 504 that is defined by interior dimensions of the first and/or the second type of standardized electrical outlet box. FIG. 5 in particular illustrates restrictors 502-503 located along back surface 103 in a position whereby restrictors 502-503 are able to engage with the interior walls of a standardized electrical outlet box.

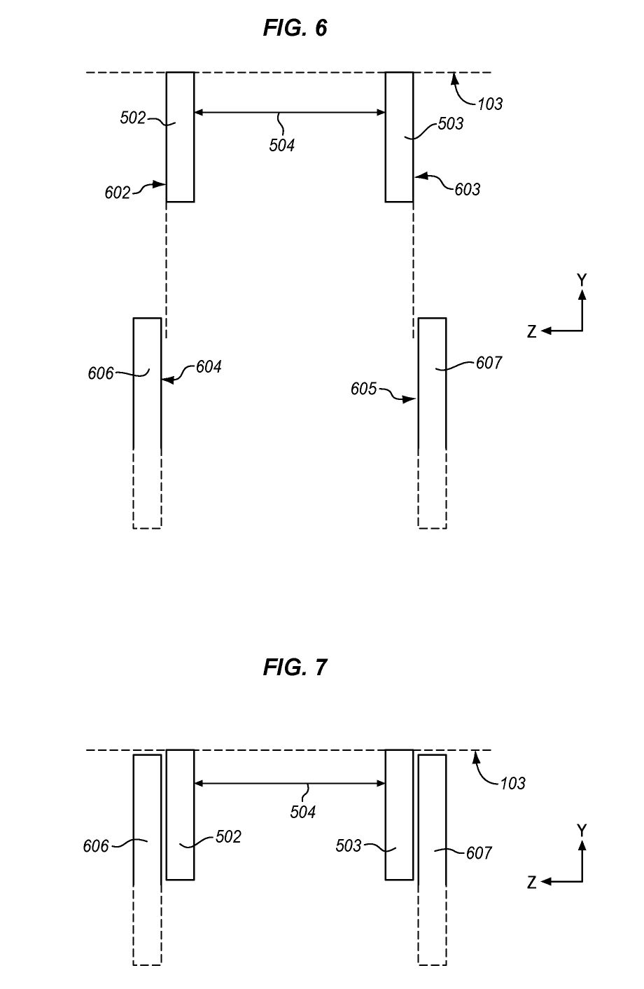

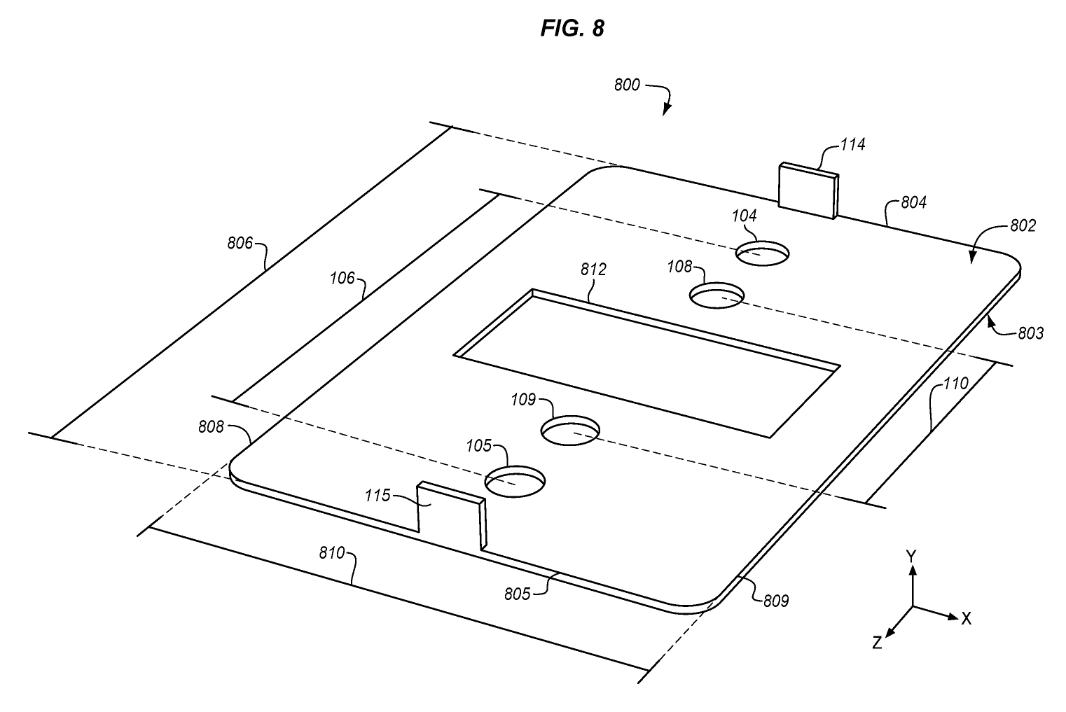

FIG. 6 is a view of restrictors 502-503 along the x-axis of FIG. 5 in an illustrative embodiment. In this view, outer surfaces 602-603 of restrictors 502-503 engage with inner surfaces 604-605 of walls 606-607 of a standardized electrical outlet box. This prevents movement of adapter plate 100 in the direction of the z-axis in FIG. 5. In particular, outer surface 602 of restrictor 502 forms a planar surface (which is into the page in FIG. 6) and is able to engage with inner surface 604 of wall 606 of a standardized electrical outlet box. Outer surface 603 of restrictor 503 forms a planar surface (also into the page in FIG. 6) and is able to engage with inner surface 605 of wall 607 of the standardized electrical outlet box. FIG. 7 is a view of restrictors 502-503 and walls 606-607 when engaged together in an illustrative embodiment.

FIG. 8 is a perspective view of another adapter plate 800 in an illustrative embodiment. Adapter plate 800 is used to mount a display device (not shown in FIG. 8) to a standardized electrical outlet box (also not shown in FIG. 8.). The display device and the standardized electrical outlet box may be similar to what was previously described.

In this embodiment, adapter plate 800 includes a front surface 802 and an opposing back surface 803. Front surface 802 is configured to be mounted towards the display device, while back surface 803 is configured to be mounted towards the standardized electrical outlet box.

Adapter plate 800 in this embodiment includes edges 804-805, which are parallel to each other and separated by a length 806 of adapter plate 800. In some embodiments, edges 804-805 may be referred to as a first edge and a second edge, respectively.

In this embodiment, adapter plate 800 further includes edges 808-809, which are parallel to each other and separated by a width 810 of adapter plate 800. In some embodiments, edges 808-809 may be referred to as a third edge and a fourth edge, respectively. Adapter plate 800 further includes an access opening 812 through adapter plate 800 from front surface 802 to back surface 803. Access opening 812 may perform similar functionality as previously described for access opening 112 of adapter plate 100 of FIG. 1.

Adapter plate 800 in this embodiment includes mounting holes 104-105, mounting holes 108-109, and tabs 114-115, all of which have been previously described with respect to FIG. 1. In the particular embodiment illustrated in FIG. 8, adapter plate 800 is rectangular. More specifically, length 806 and width 810 of adapter plate 800 are selected to cover the opening of a US 1-gang electrical outlet box.

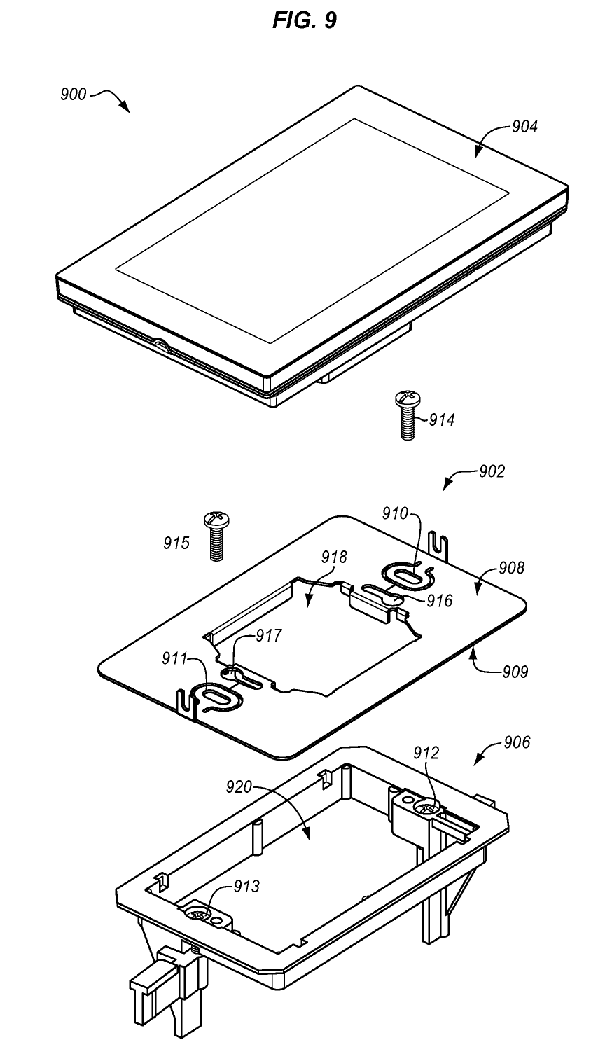

FIG. 9 is a 3-dimensional view of an assembly 900 in an illustrative embodiment. Assembly 900 in this embodiment includes an adapter plate 902, which is able to mount a display device 904 to an outlet box 906. In this embodiment, outlet box 906 is illustrated as a US 1-gang old-work box. Adapter plate 902 includes a front surface 908 which faces display device 904, and a back surface 909 which faces outlet box 906. Adapter plate 902 includes mounting holes 910-911 which align with screw receptacles 912-913 on outlet box 906. Adapter plate 902 further includes an access opening 918 through adapter plate 902 from front surface 908 to back surface 909, which align to an opening 920 into outlet box 906. Screws 914-915 of assembly 900 are used to secure adapter plate 902 to outlet box 906. In particular, screws 914-915 pass through mounting holes 910-911, and into screw receptacles 912-913. Although outlet box 906 is illustrated as an old-work box in this embodiment, outlet box 906 may comprise a new-work box in some embodiments. Adapter plate 902 in this embodiment further includes mounting holes 916-917 which line up with screw receptacles on a different type of standardized electrical outlet box, such as electrical outlet boxes in use in the EU and UK.

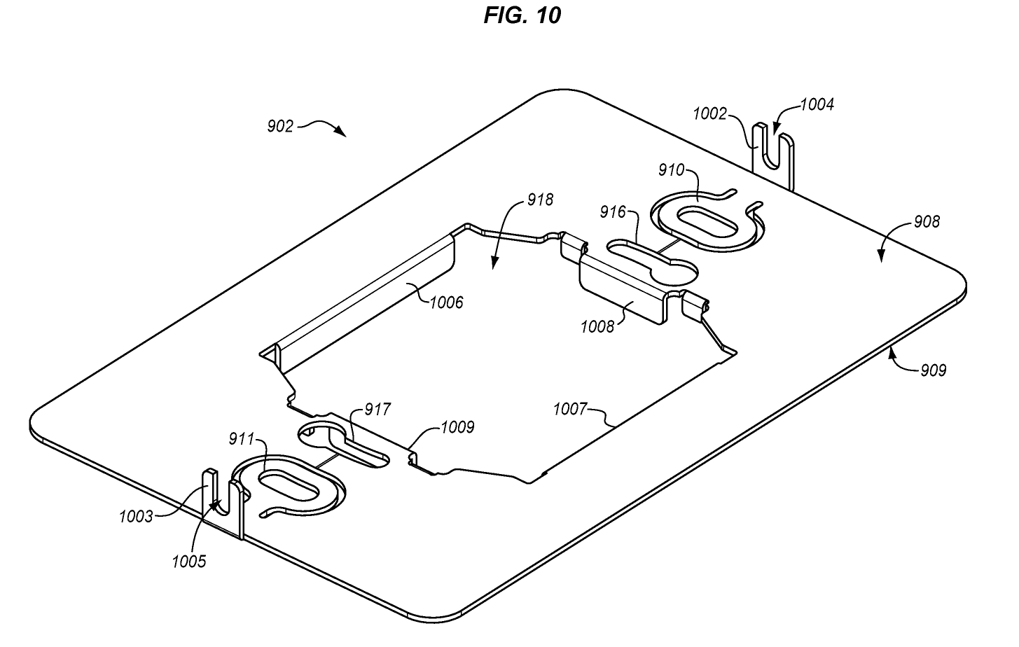

FIG. 10 is another 3-dimensional view of adapter plate 902 in an illustrative embodiment. In particular, FIG. 10 illustrates features along front surface 908 of adapter plate 902. In this view, tabs 1002-1003 of adapter plate 902 are illustrates as including notches 1004-1005. When display device 904 is mated with adapter plate 902, tabs 1002-1003 align with recesses in display device 904 (not shown in this view). Notches 1004-1005 are sized to allow a pair of screws at display device 904 to pass thorough notches 1004-1005 and secure display device 904 to adapter plate 902.

Also illustrated in FIG. 10 are restrictors 1006-1009. Restrictor 1007 is partially hidden in this view. Restrictors 1006-1009 are used to align adapter plate 902 with opening 920 of outlet box 906. Outlet box 1204 is illustrates as a UK 1-gang electrical outlet box.

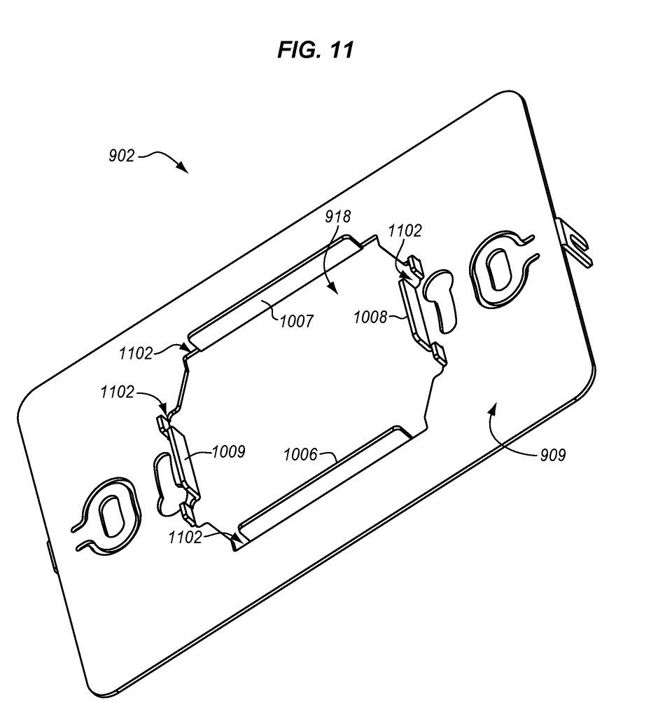

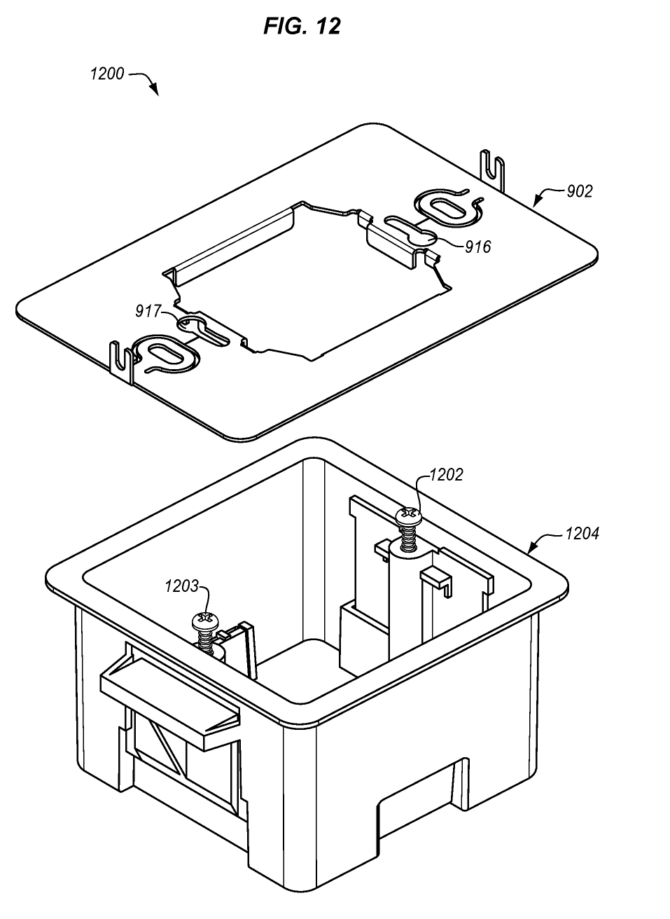

FIG. 11 is another 3-dimensional view of adapter plate 902 in an illustrative embodiment. In particular, FIG. 11 illustrates features along back surface 909 of adapter plate 902. In this view, restrictors 1006-1009 are more clearly visible. In this embodiment, restrictors 1006-1009 extend from back surface 909 of adapter plate 902 along a perimeter 1102 of access opening 918.

FIG. 12 is a 3-dimensional view of assembly 1200 in an illustrative embodiment. In this embodiment, assembly 1200 includes adapter plate 902 and an outlet box 1204. Outlet box 1204 is illustrated as a UK 1-gang electrical outlet box in this embodiment. Mounting holes 916-917 of adapter plate 902 align with screw receptacles 1202-1203 of outlet box 1204, thereby allowing display device 904 (see FIG. 9) to be mounted to both the US 1-gang electrical outlet box and the UK 1-gang electrical outlet box.

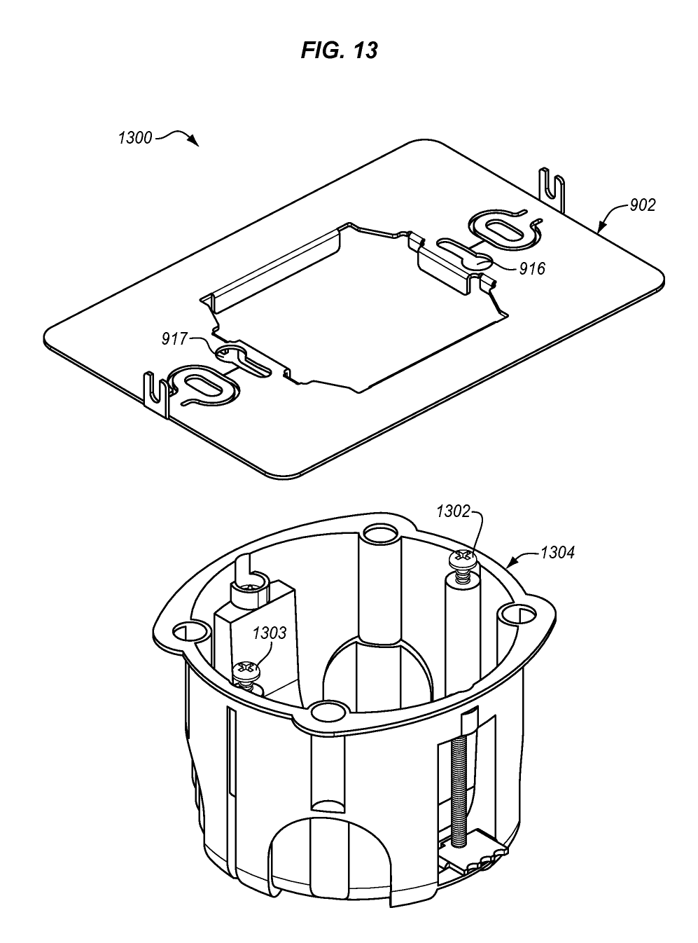

FIG. 13 is a 3-dimensional view of another assembly 1300 in an illustrative embodiment. In this embodiment, assembly 1300 includes adapter plate 902 and an outlet box 1304. Outlet box 1304 is illustrated as a EU 1-gang electrical outlet box in this embodiment. Mounting holes 916-917 of adapter plate 902 align with screw receptacles 1302-1303 of outlet box 1304, thereby allowing display device 904 (see FIG. 9) to be mounted to both the US 1-gang electrical outlet box and the EU 1-gang electrical outlet box.

The use of the adapter plates described herein allows for a display device as may be used in home automation to be mounted to a variety of standardized electrical outlet boxes in use worldwide. This type of universal mounting capability allows a single adapter plate to support a wide variety of installation environments.

Although specific embodiments were described herein, the scope is not limited to those specific embodiments. Rather, the scope is defined by the following claims and any equivalents thereof.

1. An apparatus, comprising:
an adapter plate configured to mount a display device to different types of standardized electrical outlet boxes, the adapter plate including:
a first surface configured to contact the display device;
a second surface opposite the first surface that is configured to contact a selected one of the different types of standardized electrical outlet boxes;
a first pair of mounting holes through the adapter plate that are separated from each other by a distance defined by screw receptacles on a first type of the different types of standardized electrical outlet boxes;
a second pair of mounting holes through the adapter plate that are separated from each other by a distance defined by screw receptacles on a second type of the different types of standardized electrical outlet boxes;
a pair of tabs that extend from the first surface that are configured to mate to the display device; and
an access opening through the adapter plate that is sized to pass an electrical cable from the selected one of the different types of standardized electrical outlet boxes to the display device,
wherein the first pair of mounting holes, the second pair of mounting holes, and the pair of tabs align on an axis.

2. The apparatus of claim 1, wherein:
the pair of tabs extend from the first surface at a perimeter of the adapter plate.

3. The apparatus of claim 1, wherein:
the pair of tabs each form planar surfaces that are perpendicular to the first surface; and
the pair of tabs each include a notch that is sized to pass a screw that secures the display device to the adapter plate.

4. The apparatus of claim 1, wherein:
the distance between the first pair of mounting holes is defined by a United States 1-gang work box; and
the distance between the second pair of mounting holes is defined by a European round wall box.

5. The apparatus of claim 1, further comprising:
at least two restrictors that extend from the second surface and are separated by distance defined by an interior space of the first type of the different types of standardized electrical outlet boxes and the second type of the different types of standardized electrical outlet boxes.

6. The apparatus of claim 5, wherein:
the at least two restrictors each form planar surfaces that are perpendicular to the second surface and engage with interior walls of the first type of the different types of standardized electrical outlet boxes and the second type of the different types of standardized electrical outlet boxes.

7. The apparatus of claim 5, wherein:
the at least two restrictors extend from the second surface from a perimeter of the access opening.

8. An apparatus, comprising:
a rectangular adapter plate configured to mount to different types of standardized electrical outlet boxes, the rectangular adapter plate including:
a first surface;
a second surface opposite the first surface;
an access opening through the rectangular adapter plate that is sized to pass an electrical cable;
a first pair of mounting holes through the rectangular adapter plate that are separated from each other by a distance defined by screw receptacles of a first type of the different types of standardized electrical outlet boxes, wherein the first pair of mounting holes are disposed between the access opening and a perimeter of the rectangular adapter plate;
a second pair of mounting holes through the rectangular adapter plate that are separated from each other by a distance defined by screw receptacles of a second type of the different types of standardized electrical outlet boxes, wherein the second pair of mounting holes are disposed between the first pair of mounting holes and the access opening; and
a pair of tabs that extend from the first surface,.
wherein the first pair of mounting holes, the second pair of mounting holes, and the pair of tabs align on an axis.

9. The apparatus of claim 8, wherein:
the pair of tabs extend from the first surface at a perimeter of the rectangular adapter plate.

10. The apparatus of claim 9, wherein:
the pair of tabs extend from the first surface and are proximate to the first pair of mounting holes.

11. The apparatus of claim 8, wherein:
the pair of tabs each form planar surfaces that are perpendicular to the first surface; and
the pair of tabs each include a notch that is sized to pass a screw that secures a display device to the rectangular adapter plate.

12. The apparatus of claim 8, wherein:
the distance between the first pair of mounting holes is defined by a United States 1-gang work box; and
the distance between the second pair of mounting holes is defined by a European round wall box.

13. The apparatus of claim 8, further comprising:
at least two restrictors that extend from the second surface and are separated by distance defined by an interior perimeter of the first type of the different types of standardized electrical outlet boxes and the second type of the different types of standardized electrical outlet boxes.

14. The apparatus of claim 13, wherein:
the at least two restrictors each form planar surfaces that are perpendicular to the second surface and are configured to engage with interior walls of the first type of the different types of standardized electrical outlet boxes and the second type of the different types of standardized electrical outlet boxes.

15. The apparatus of claim 13, wherein:
the at least two restrictors extend from the second surface at a perimeter of the access opening.

16. An apparatus, comprising:
an adapter plate configured to mount a display device to different types of standardized electrical outlet boxes, the adapter plate including:
a first surface configured to contact the display device;
a second surface configured to contact a selected one of the different types of standardized electrical outlet boxes;
an access opening through the adapter plate that is sized to pass an electrical cable from the selected one of the different types of standardized electrical outlet boxes to the display device;
a first edge and a second edge parallel to each other and separated from each other by a length of the adapter plate;
a third edge and a fourth edge parallel to each other and separated from each other by a width of the adapter plate;
a first mounting hole that is disposed between the first edge and the access opening;
a second mounting hole that is disposed between the second edge and the access opening, wherein the first mounting hole and the second mounting hole are separated from each other by a distance defined by screw receptacles on a first type of the different types of standardized electrical outlet boxes;
a third mounting hole that is disposed between the first mounting hole and the access opening;
a fourth mounting hole that is disposed between the second mounting hole and the access opening, wherein the third mounting hole and the fourth mounting hole are separated from each other by a distance defined by screw receptacles on a second type of the different types of standardized electrical outlet boxes; and
a first tab and a second tab that extend from the first surface and are configured to attach to the display device,
wherein the first mounting hole, the second mounting hole, the third mounting hole, the fourth mounting hole, the first tab, and the second tab align on an axis.

17. The apparatus of claim 16, wherein:
the first tab and the second tab extend from the first surface at an outer perimeter of the adapter plate.

18. The apparatus of claim 16, wherein:
the first tab and the second tab each form planar surfaces that are perpendicular to the first surface; and
the first tab and the second tab each include a notch that is sized to pass a screw that secures the display device to the adapter plate.

19. The apparatus of claim 16, wherein:
the distance between the first mounting hole and the second mounting hole is defined by a United States 1-gang work box; and
the distance between the third mounting hole and the fourth mounting hole is defined by a European round wall box.

20. The apparatus of claim 16, further comprising:
at least two restrictors that extend from the second surface and are separated by distance defined by an interior space of the first type of the different types of standardized electrical outlet boxes and the second type of the different types of standardized electrical outlet boxes.

21. The apparatus of claim 20, wherein:
the at least two restrictors each form planar surfaces that are perpendicular to the second surface and are configured to engage with interior walls of the first type of the different types of standardized electrical outlet boxes and the second type of the different types of standardized electrical outlet boxes.

22. The apparatus of claim 20, wherein:
the at least two restrictors extend from the second surface from a perimeter of the access opening.
